(19) United States
(12) Patent Application Publication
(10) Pub. No.: US 2010/0128898 A1
(43) Pub. Date: May 27, 2010

(54) METHOD AND APPARATUS FOR OPERATION SEQUENCING OF AUDIO AMPLIFIERS

(75) Inventor: LANCE M. WONG, San Francisco, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: NUVOTON TECHNOLOGY CORPORATION, Hsin-Chu (TW)

(21) Appl. No.: 12/324,452

(22) Filed: Nov. 26, 2008

(51) Int. Cl. H04B 15/00; H03F 1/14

(52) U.S. Cl. 381/94.5; 330/51

(57) ABSTRACT

A circuit, system and method provide the suppression of pop at power up of audio amplifiers. The output driver is tri-stated at power up and is enabled after a predetermined time constant. In one embodiment, the output driver includes a MOS transistor pair connected in a push-pull configuration and switches that are under the control of a delay circuit. the. The output driver and the delay circuit may be part of a power amplifier in an audio system. The delay circuit may be implemented using mixed analog and digital signals or a digital controller configured to receive a clock frequency and execute a machine readable program code. The delay circuit is responsive for the start-up behavior of the audio system.

### CROSS-REFERENCES TO RELATED APPLICATIONS

NOT APPLICABLE

### STATEMENT AS TO RIGHTS TO INVENTIONS MADE UNDER FEDERALLY SPONSORED RESEARCH OR DEVELOPMENT

NOT APPLICABLE

### REFERENCE TO A “SEQUENCE LISTING,” A TABLE, OR A COMPUTER PROGRAM LISTING APPENDIX SUBMITTED ON A COMPACT DISK

NOT APPLICABLE

### BACKGROUND OF THE INVENTION

The present invention relates generally to electronic circuit techniques. More specifically, embodiments of the present invention provide techniques for suppressing transients in amplifier circuits. Merely by way of example, the invention has been applied to audio power amplifiers for suppressing power up transients (e.g., popping noises) when the power amplifiers are turned on. But it would be recognized that the invention has a much broader range of applicability.

Amplifier circuits are prevalent in modern electronic devices. For example, an audio amplifier is an electronic amplifier that amplifies low-power audio signals to a level suitable for driving sound producing devices, such as loudspeakers or headphones. When audio power amplifiers use a single power supply, their output is usually biased at the mid-point of the power supply voltage. A large AC coupling capacitor is connected between the output of the amplifier and a loudspeaker. The capacitor is used to block any DC current from flowing through a loudspeaker that has low impedance.

FIG. 1 is a block diagram of an audio power amplifier, as known in the art. The audio amplifier consists of an amplifier Amp, an input coupling capacitor Cin. The amplifier is a linear amplifier operating in class AB. The output of the amplifier is biased through a bias voltage Vbias, which may be implemented using a voltage divider. The voltage divider includes a first resistor R1, a second resistor R2, and a decoupling capacitor C1. The resistors R1 and R2 may have the same value and provide a bias voltage at the mid-point of the power supply Vcc for an optimal output voltage swing. A resistive load, e.g., a loudspeaker or an earphone, is AC coupled to the biased amplifier output through a coupling capacitor Cb. The coupling capacitor Cb passes the AC signal but blocks the DC voltage. The sound source may be an analog signal coming directly from a radio receiver, a microphone, a record player, or a cassette player, etc. Or the sound source may be a digital signal coming from a music CD that is converted into an analog signal through the use of a digital analog converter DAC. The sound source is filtered by a low-pass filter that can be a passive filter, an active filter, or a complex filter including equalization and tone adjustment.

Even though conventional audio amplifiers are widely used, they suffer from many limitations. One of the limitations is pop noise or click noise that can be produced in transient states of the amplifier. For example, a pop noises can often be heard during power-on of an audio amplifier. Conventional circuit techniques are expensive and often ineffective.

Therefore, cost effective circuits and methods for eliminating or at least suppressing amplifier transients, such as pop noises, are highly desirable.

### BRIEF SUMMARY OF THE INVENTION

Whenever an amplifier is powered on, its internal nodes can be charged at different speeds causing transient currents to flow in an uncontrollable manner. Transient currents may flow through the AC coupling capacitor to the loudspeaker, which generates pop or click sound. In the following description, the term “pop” will be used for unwanted sound generated at power up and power down of an audio amplifier.

Embodiments of the present invention provide circuits and methods for suppressing transients in an electronic amplifier circuit. Merely by way of example, the invention has been applied to suppressing pop noise in an audio power amplifier in integrated circuits including audio codec. But it would be recognized that the invention has a much broader range of applicability.

In a specific embodiment, the present invention provides a circuit that includes an output driver configured to drive a low impedance load (e.g., a loudspeaker) after a predetermined time period at start up. The output driver can be set in a tri-state mode or in an active mode through electronic switches that are controlled by a delay circuit. In one embodiment, the output driver uses a single power supply and drives the low impedance load through a coupling capacitor.

In one embodiment, the output driver includes a PMOS and an NMOS transistor pair connected in a push-pull configuration. The transistor pair is controlled by the electronic switches that can be implemented using MOS transistors.

In one embodiment, the predetermined time period is provided by the delay circuit that includes a digital controller configured to receive a clock frequency and output at least a first control signal and a second control signal for controlling the electronic switches. The first and second control signals may have opposite logic states, e.g., “0” and “1”.

The present invention provides an audio amplifier including a first (preamplifier) stage, a second (intermediate) stage, and a third (driver) stage. The amplifier further includes a frequency compensation capacitor that is coupled between the output of the first stage and the output of the third stage. Additionally, the amplifier also includes a delay circuit configured to receive a clock frequency and generate a start-up sequence to sequentially turn on the first, second, and third stages. In a specific embodiment, the start-up sequence only includes the turning-on of the third (driver) stage after a predetermined time constant.

In one embodiment of the present invention, the driver stage is only turned on after the compensation capacitor reaches a predetermined operation point. This will ensure that a feedback loop is established and the audio amplifier is in a stable operating condition.

In another embodiment of the present invention, the first stage has differential inputs and the third stage has a push-pull structure. The push-pull structure may include a pair of complementary transistors, e.g., PMOS and NMOS transistors.

In yet another embodiment of the present invention, the push-pull structure may be set in a tri-state mode and become operational only after the predetermined time constant. In one embodiment, the predetermined time constant is provided using a digital controller that is configured to receive a clock frequency and execute a machine readable program code stored in a memory. The memory may be a flash memory, an SRAM, a DRAM, a ROM, an EPROM, or an EEPROM.

In yet another embodiment of the present invention, the push-pull configuration of the output driver comprises a first output transistor and a second output transistor, with the first output transistor having a first terminal substantially coupled to the power supply, a second terminal and a third terminal, the second transistor having a fourth terminal coupled to the third terminal, a fifth terminal, and a sixth terminal coupled to ground. The push-pull configuration further comprises a first switch transistor having a seventh terminal coupled to the power supply, an eighth terminal coupled to the first control signal, a ninth terminal coupled to the second terminal, and a second switch transistor having a tenth terminal coupled to the fifth terminal, an eleventh terminal coupled to the second control signal and a twelfth terminal substantially coupled to ground.

According to yet another embodiment, a method of suppressing transients at power up comprises providing an output driver being capable of operating in a tri-state mode and in a class AB mode and providing a delay circuit configured to turn on the output driver after a predetermined time constant. The output driver is turned on after the predetermined time constant.

In one embodiment of the present invention, the predetermined time constant is a function of an operating point which is characterized by a gate-source (Vgs) voltage.

The following detailed description together with the accompanying drawings will provide a better understanding of the nature and advantage of the present invention.

### BRIEF DESCRIPTION OF THE DRAWINGS

FIG. 1 is a is a block diagram of a audio power amplifier, as known in the art.

FIG. 2A is a block diagram of a two-stage audio power amplifier, in accordance with one embodiment of the present invention.

FIG. 2B is a simplified circuit of a two-stage audio power amplifier according to one embodiment of the present invention.

FIG. 3A is a block diagram of a 3-stage audio power amplifier, in accordance with one embodiment of the present invention.

FIG. 3B is a simplified block diagram of a 3-stage audio power amplifier, in accordance with one embodiment of the present invention.

FIG. 3C is a simplified circuit of the 3-stage audio power amplifier in FIG. 3B, in accordance with one embodiment of the present invention.

FIG. 4 is a diagram illustrating simulation results of the circuit in FIG. 3C, in accordance with one embodiment of the present invention.

### DETAILED DESCRIPTION OF THE INVENTION

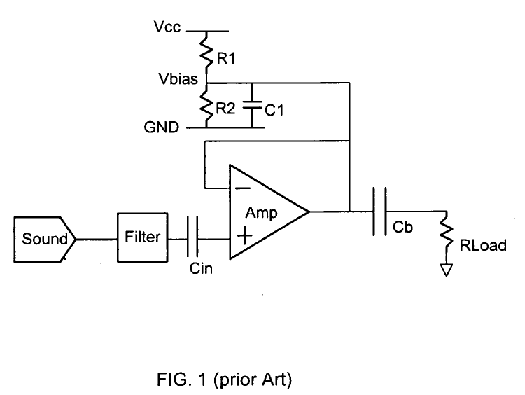

As noted above, conventional amplifier circuits can be susceptible to transient noises. Specifically, in an audio amplifier, power-on transient can create pop noises which are undesirable. For example, in the audio amplifier described above with reference to FIG. 1, in a steady-state, no current flows through the loudspeaker, i.e., the coupling capacitor has the bias voltage on the side connected to the amplifier output and zero volt (Ground) on the side connected to the loudspeaker. Additionally, before power is applied to the amplifier, capacitors Cin and C1 have no charge across them. During power up, these capacitors will begin to charge at different time constants. The time constants depend on several factors such as the values of resistors R1 and R2, the input impedance of the amplifier Amp, the amplitude of the sound source, the output impedance and drive capability of the low-pass filter, etc. Due to the different charge times of the capacitors Cin and C1, a current will flow across the coupling capacitor Cb and result in pop sounds in the loudspeaker. These pop sounds are not only unpleasant to the listener, but also can damage the loudspeaker.

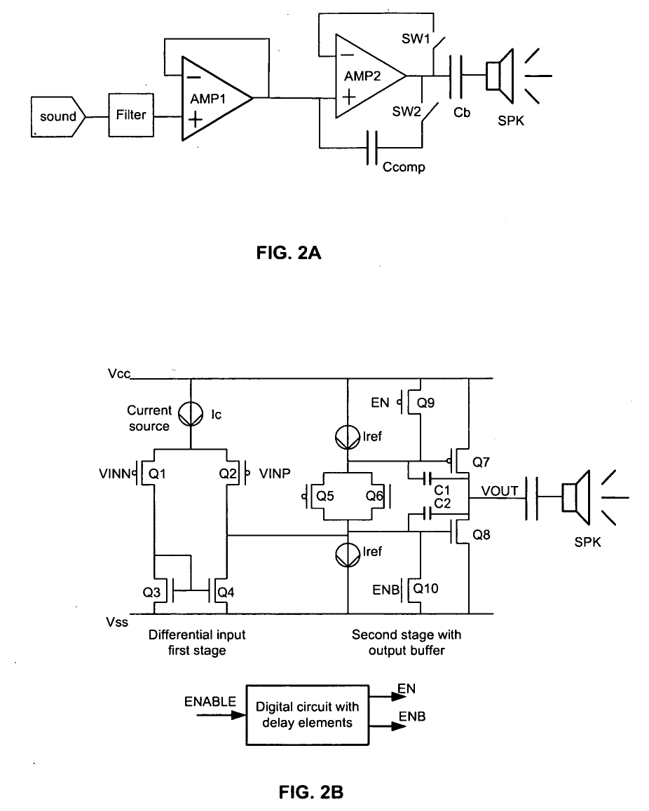

FIG. 2A is a block diagram of a two-stage audio power amplifier according to one embodiment of the present invention. Two operational amplifiers AMP1 and AMP2 configured as common-source amplifiers are cascaded. The compensation capacitor Ccomp is dominant over other capacitors and operates as a negative feedback circuit. Its objective is primarily to provide stability to the amplifier and secondary to obtain a nearly constant phase over the range of operating frequencies. The compensation capacitor Ccomp is coupled to the coupling capacitor Cb on one end and to the input of the amplifier Amp2 on the other end. During power up, the capacitor Ccomp may be charged at a rate that is different than the coupling capacitor Cb. The unequal charged rates may result in pop sounds at the sound producing device SPK. To eliminate the pop effect, switches SW1 and SW2 are inserted at the output driver of AMP2 to isolate the coupling capacitor Cb from the amplifier during power up. The output driver of the amplifier is connected to the capacitor Cb only when Ccomp is charged to a predetermined operating point.

FIG. 2B is a simplified circuit of a two-stage audio power amplifier, in accordance with one embodiment of the present invention. The first stage is a differential input common-source amplifier and the second stage is a common-source amplifier including an output driver. Transistors Q1 and Q2 provide the connection to the differential inputs Vinn and Vinp, and transistors Q3 and Q4 provide the current mirror supply for the first stage amplifier. The current source Ic is generally used to bias the transistors Q1 and Q2. Q5 and Q6 are part of a voltage reference circuit configured to bias the output driver at Vcc/2 (mid rail). The output driver includes transistors Q7 and Q8, which are connected as a push-pull configuration. Capacitors C1 and C2 can be integrated on-chip as MIM capacitors connected between the drain and the gate of respective transistors Q7 and Q8. C1 and C2 have high capacitance value resulting from the Miller effect, which effectively multiplies the capacitive value of C1 and C2 by the factor 1+|Av|, where Av is the voltage gain of the amplifier. The Miller integrator or capacitance multiplier allows this circuit to integrate the capacitors C1 and C2 on-chip and generate very long charge time constants.

During power up, all nodes of the two-stage amplifier are charged to their operating values except the gates of Q7 and Q8 due to the large value of C1 and C2. Q7 and Q8 will turn on gradually, and the turn-on time of Q7 and Q8 depends closely to the respective value of C1 and C2. However, when Q7 and Q8 did not turn on at the same time, a current would flow through the coupling capacitor and result in clicks or pops in the load (e.g., loudspeaker). These pop sounds are not only unpleasant to the listener, but also can damage the load.

According to one embodiment of the present invention, transistors Q9 and Q10 are added to the push-pull structure of the output driver. Q9 is connected between the gate (base) of Q7 and Vcc and is switched on or off by control signal EN. Similarly, Q10 is connected between the gate (base) of Q8 and Vss and is switched on or off by control signal ENB. In one embodiment, Q9 is a PMOS transistor and Q10 is an NMOS transistor. The size of Q9 and Q10 can be small as they operate as electronic switches to turn off the respective driver transistors Q7 and Q8 during power up. In one embodiment, EN is logic “0” and ENB is logic “1” during power up so that a voltage substantially close to Vcc is applied to the gate of Q7 and a voltage substantially close to Vss is applied to the gate of Q8 resulting in both transistors Q7 and Q8 to be off and the driver output to be tri-stated. Only when all nodes of the amplifier reach their respective operating points that the control signals EN and ENB reverse their respective logic state and turn off Q9 and Q10.

According to one embodiment of the present invention, the control signal EN and ENB are generated from a digital circuit including digital delay elements. The delay elements can be implemented using combinational logic and flip-flops that are clocked by a clock source. The digital circuit may include an input signal ENABLE that activates the delay elements. The ENABLE signal may be coupled to an input pin configured to receive a trigger signal from a user, or it may coupled to an on-chip power-on-reset circuit output, or it may be an input signal coupled to a control register whose content can be updated through the use of a control port. The control register, the control port, and the digital circuit may be part of an audio system, e.g., a codec.

In one embodiment of the present invention, the delay elements can be implemented using a mono-stable vibrator that generates a one-shot pulse. When triggered by the Enable signal, the mono-stable vibrator will switch to an unstable position for a period of time and then return to its stable state. The period of time may be determined by external discrete R and C components. The ENABLE signal may be asserted by the user at any time or at power up by the power-on reset circuit. Alternatively, the delay elements may be implemented using synchronous or asynchronous digital counters and/or a combination thereof. For example, synchronous and asynchronous counters can be implemented using D-flip-flops, JK-flip-flops, T-flip-flops, latches, and/or combination logic that divide the clock source to lower clock frequencies.

A problem arises for the design of a three-stage audio power amplifier. Because the frequency compensation capacitor is connected between the output of the first stage and the third stage (the output driver), the output driver may become active before the compensation capacitor and other nodes reach their steady states. While the compensation capacitor is charging toward its steady state, transient currents may flow across the output driver and cause pop and click sound at the loudspeaker.

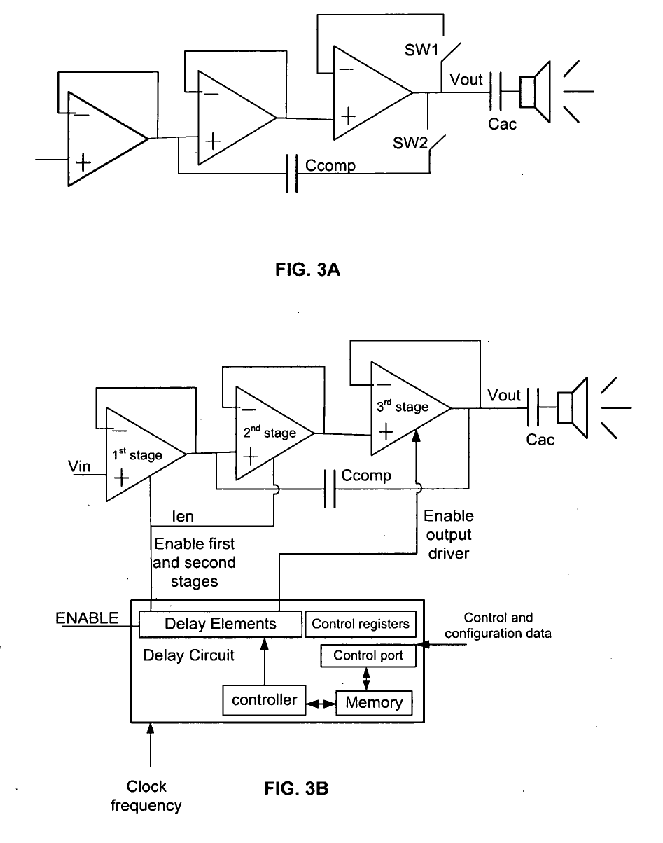

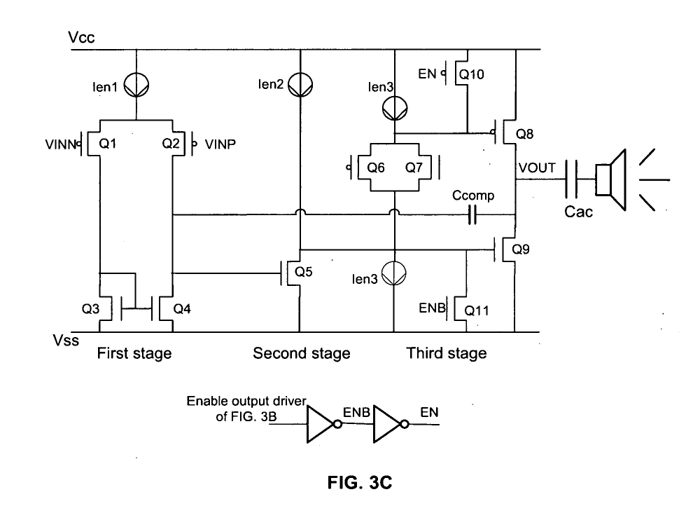

FIG. 3A is a block diagram of a 3-stage audio power amplifier according to one embodiment of the present invention. The 3-stage power amplifier consists of three common-source amplifiers connected in series and configured as a non-inverting voltage follower. The output of the third (driver) stage is connected with the input of the second stage through a frequency compensation capacitor Ccomp. This amplifier structure has at least 3 poles. More compensation capacitors and other circuits can be used in the feedback loop, but the amplifier will have more poles and the frequency compensation becomes complicated. This 3-stage amplifier may produce a significant pop sound when powered up due to the different charging stages of the capacitors Ccomp and Cac so that a current will flow through the coupling capacitor Cac. In one embodiment of the present invention, the output driver will be tri-stated during power up. The tri-state is achieved by electronic switches SW1 and SW2.

FIG. 3B is simplified block diagram of a 3-stage audio power amplifier, in accordance with one embodiment of the present invention. The power amplifier comprises a first stage (preamplifier), a second (intermediate) stage, and a third stage (driver). A frequency compensation capacitor Ccomp is coupled between the output of the third stage and the output of the first stage to introduce a dominant pole at low frequency to ensure stability of the amplifier. Each stage of the amplifier may be powered up according to a startup sequence. The startup sequence can be controlled by a delay circuit configured to receive a clock frequency. The delay circuit may include digital counters adapted to divide down the clock frequency and produce delay elements. The delay circuit may include a digital processor (controller) configured to execute a machine a readable program code stored in a memory and generate the delay elements. The delay elements may be used to produce the startup sequence. The memory can be one of the flash memory, an SRAM, a DRAM, a ROM, or an EEPROM. In one embodiment, only one delay element may be used as the Enable signal to turn on the output driver. In another embodiment, the delay elements may have different time constants which are programmable by a user through a control port. Time constants of the delay elements or machine readable codes may be configured or written into the delay circuit through the control port.

FIG. 3C is a simplified circuit of the 3-stage audio power amplifier shown in FIG. 3B, in accordance with one embodiment of the present invention. The first stage includes a differential transistor pair Q1 and Q2 with a current mirror Q3 and load Q4. The differential pair Q1 and Q2 are biased at an operating point determined by current source Ien1. The second stage includes a common-source amplifier with a current source load Ien2. In one embodiment, current sources Ien1 and Ien2 can be switched on and off by the Ien signal (FIG. 3B). In another embodiment, the Ien signal is not used and only the third (driver) stage is switched on by the Enable signal. The third stage includes the bias stage including in part the transistors Q6 and Q7 and the output driver. The output driver comprises the output transistors Q8 and Q9 connected in a push-pull configuration. The output of the push-pull structure is coupled to the input of the second stage through a frequency compensation capacitor Ccomp. Without any compensation capacitor, the circuit would have at least three poles which are located very closely to each other. This makes the phase of the amplifier drop below to −180 degree faster than the gain to 0 dB and cause a stability problem.

In one embodiment, the output driver comprises a complementary transistor pairs Q8 and Q9 configured in a push-pull structure. The output of the push-pull structure is biased at mid-rail and coupled to a sound producing load through an AC coupling capacitor Cac. The output driver further comprises transistor Q10 that operates as an electronic switch and connects the gate (base) of the transistor Q8 substantially to the Vcc level at start up so that Q8 is switched off. The output driver also includes transistor Q11 that operates as an electronic switch and connects the gate (base) of Q9 substantially to the Vss level so that Q9 is switched off at the start-up phase.

In one embodiment of the present invention, the output driver is implemented using CMOS technology, where Q8 is a PMOS transistor and Q9 is an NMOS transistor. Q10 may be implemented as a PMOS transistor having the source and drain terminals connected to the respective gate of Q8 and Vcc and a gate terminal configured to receive control signal EN. Similarly, Q11 may be implemented as an NMOS transistor having the drain and source connected to the respective gate of Q9 and Vss and a gate terminal configured to receive control signal ENB. Thus, Q8 and Q9 can be switched off, i.e., the push-pull structure is tri-stated at power up when EN is “0” and ENB is “1”. No current will flow through the output driver so that pop can be eliminated. The output driver will be enabled when all nodes of the amplifier are in steady states. In one embodiment, the output driver is enabled by reversing the logic state of control signals EN and ENB.

In one embodiment of the present invention, the associated RC time constant Tc is closely related to the size of the compensation capacitor. The size of the compensation capacitor depends on the phase margin, i.e., stability, of the three-stage power amplifier. The time constant can be estimated by the following formula:

Tc=C*V/I (1)

where C is the value of the frequency compensation capacitor Ccomp, V is the charge voltage threshold, and I is the charge current.

In one embodiment, Vcc is 3.3V and the charge threshold voltage corresponds to the gate-source voltage Vgs of transistor Q5 and is about 1.0 V.

The use of a feedback compensation capacitor Ccomp has an impact on the switch-on behavior. With a feedback capacitor the switch-on behavior is somewhat worse. The present invention provides a switch-on mechanism and method that enable a switch-on with negligible or no pop at all.

With asymmetrical power supply (e.g., Vcc at 3.3V and Vss at 0V), the switch-on behavior depends on the rise time of the power supply and the compensation capacitor. With slow rise of the power supply, there may not be switch-on pop. When the rise time is short, the pop effect can become somewhat worse.

According to one embodiment of the present invention, the 3-stage power amplifier is powered up sequentially. The first and second stages are powered up first while the output driver is still in tri-stated. In one embodiment, the power sequence is performed by a delay circuit, which includes a processor (controller) operating at a certain clock frequency and executing a machine readable program code. The program code may include a loop or multiple loops being repeated a number of times. The delay circuit may include a serial port such as an inter-integrated circuit (I2C), a serial peripheral interface (SPI) serial data link, or any user-defined interface.

In one embodiment of the present invention, the delay circuit may include digital counters configured to generate delay time constants. The digital counters can be implanted as synchronous or asynchronous counters.

In another embodiment, the digital circuit and the power amplifier are implemented in the same integrated circuit using CMOS technology.

In yet another embodiment, the digital circuit and the power amplifier are a small part of a large audio codec system.

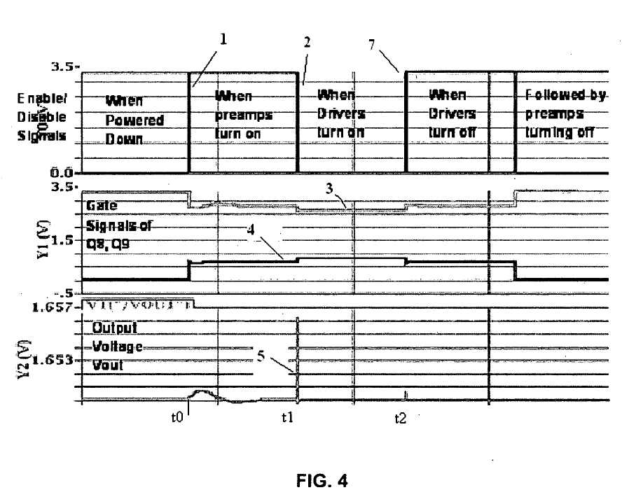

FIG. 4 is a timing diagram illustrating the power-up behavior of the circuit of FIG. 3C. Trace 1 is the power supply configured to power up the amplifier. Trace 2 is the EN/ENB signals configured to power up the output driver. Trace 3 is the voltage characteristic at the gate of the output transistor Q8 and trace 4 is the voltage characteristic of the output transistor Q9. Trace 5 is the voltage at the output Vout of the push-pull structure. At turn-on instant t0, i.e., the amplifier is partially enabled, i.e., the first and second stages are turned on, EN is 0V and ENB is at Vcc, and both transistors Q10 and Q11 are on leading to Q8 and Q9 in the off state and the output driver is tri-stated and is biased to Vcc/2 (1.65V). Between trace 1 and trace 2, the first and second stages are on and all nodes of the amplifier are steady. At time t1, Q10 and Q11 are switched off (indicating by Trace 2) and the output transistors Q8 and Q9 are enabled. Traces 3 and 4 depict the respective voltage characteristics of the gate of transistors Q8 and Q9. Due to the different switch-on time of Q8 and Q9, a small voltage glitch may occur (indicated by Trace 5). In one simulation, the glitch at the output driver has an amplitude about 6 mV (1.650V to 1.656V) and a time duration of less than 1 ms. Due to its small amplitude and time duration, the voltage glitch is not audible.

Trace 5 also shows the power-off behavior at time t2. According to one embodiment of the present invention, the output driver is turned off first (Trace 7). The resulting glitch is negligible (less than 1 mV) at the output driver.

Many advantages can be achieved in accordance with embodiments of the present invention. For example, the power-up sequence can be obtained from the delay circuit running instructions stored in a memory. In one embodiment, the memory may be integrated on the same chip as the delay circuit and the audio power amplifier. In one embodiment, the output driver is enabled by a delay element, which may be implemented using digital counters. The delay element can be user programmable and adjusted according to specific applications. In one embodiment of the present invention, the delay circuit includes a controller executing a machine readable program code. The program code may include a loop or multiple loops being repeated a fixed number of times to generate the predetermined time constant. The digital circuit further includes a control port adapted to receive user configuration and control data for enabling a flexible amplifier design. In another embodiment, the Enable signal for the output driver may be triggered with the use of an external trigger input pin or a power-on reset event. In yet another embodiment, the Enable signal can be triggered by an ENABLE bit stored in an associated control register. The ENABLE bit can be updated by user through the control port. For example, the ENABLE bit can be updated according to specific applications such as “changing channel”, “standby”, “mute”, etc. In contrast, approaches according to prior art are fixed and any modification in power-up sequence would require hardware modification and in some cases replacement of components. And in some cases, the startup sequencing delays are limited to a narrow range due to the physical size of the components and/or their costs.

In one embodiment of the present invention, the audio amplifier operates in class AB with a single power supply, i.e., Vcc equal 3.3V and Vss equal 0V. The charge current Ien2 is about 20 uA, the compensation capacitor is charged to the gate-source voltage Vgs of transistor Q5 of the second stage, which is about 1.0V, and the compensation capacitor is 8 pF. According to Equation (1), the time constant for charging the compensation capacitor is the output driver to switch from tri-stated to normal operation mode is therefore about 0.4 microsecond. The delay time for enabling the output driver may be selected to be about 12 ms, which is significantly larger than the charge time constant of the compensation capacitor. The delay time constant for enabling the output driver must be significantly larger than the charge time Tc of the compensator capacitor (Tdelay>>Tc) to ensure a pop-free start-up operation of the amplifier.

Specific details are given in the description to provide a thorough understanding of the embodiments. However, it will be understood by one of ordinary skill in the art that the embodiments may be practiced without these specific details. For example, the first stage of the amplifier may be single-ended. The design is not limited to single power supply. The output driver may be duplicated. The duplicated output driver may be connected in parallel with the output driver for driving a differential load. The duplicated output driver may be powered with a voltage that is the negative of the output driver power supply in order to double the differential output magnitude. The embodiments may be implemented using CMOS, BiCMOS, bipolar technology, and/or a combination thereof. The delay elements may be implemented using a microcontroller, a microprocessor, mixed signals, ROM, RAM, and/or in combination with machine readable program codes (software). They may be designed using RTL codes, hardware description languages (HDL), schematic captures, and/or any combination thereof.

Having described several embodiments, it will be recognized by those skilled in the art that various modifications, alternative constructions, and equivalents may be used without departing from the spirit of the invention. For example, the above elements may merely be a component of a large system, wherein other rules may take precedence over or otherwise modify the application of the invention. Accordingly, the above description should not be taken as limiting the scope of the invention, which is defined in the following claims.

What is claimed is:

1. A circuit comprising:
an output driver configured to drive a load;
a plurality of electronic switches configured to turn on the output driver after a predetermined time constant, and
a delay circuit including at least one delay element configured to generate the predetermined time constant and to produce at least one enable signal to control the plurality of electronic switches.

2. The circuit of claim 1 wherein the delay circuit comprises a trigger input configured to start the at least one delay element.

3. The circuit of claim 1 wherein the at least one enable signal comprises a first control signal and a second control signal.

4. The circuit of claim 1 wherein the delay circuit comprises a digital controller configured to receive a clock frequency and execute a machine readable program code stored in a memory.

5. The circuit of claim 4 wherein the memory is one of the flash memory, an SRAM, a ROM, an EPROM, or an EEPROM.

6. The circuit of claim 1 wherein the output driver comprises:
a first driver transistor, the first driver transistor having a first terminal coupled to a first supply source, a second terminal, and a third terminal;
a second driver transistor, the second driver transistor having a fourth terminal coupled to the third terminal, a fifth terminal, and a sixth terminal coupled to a second supply source;
a first switch transistor having a seventh terminal coupled to the first supply source, an eighth terminal coupled to the first control signal, a ninth terminal coupled to the second terminal; and
a second switch transistor having a tenth terminal coupled to the fifth terminal, an eleventh terminal coupled to the second control signal and a twelfth terminal coupled to the second supply source.

7. The circuit of claim 6 wherein the first driver transistor and the second driver transistor are configured in a push-pull structure.

8. The circuit of claim 6 wherein the first driver transistor is a PMOS transistor and the second driver transistor is an NMOS transistor.

9. The circuit of claim 6 wherein the first and second control signals have opposite logic states.

10. The circuit of claim 6 wherein the first supply source has a higher voltage level than the second supply source.

11. The circuit of claim 1 wherein the plurality of electronic switches comprises at least the first and second switch transistors.

12. An audio amplifier comprises:
a preamplifier stage including a first stage output and configured to receive an analog signal;
an intermediate stage coupled to the preamplifier stage;
a driver stage coupled to the intermediate stage and including a driver output configured to drive a sound producing device in response to at least one enable signal;
a frequency compensation capacitor being coupled between the first stage output and the driver output, and
a delay circuit configured to receive a clock frequency and generate the at least one enable signal after a predetermined time period.

13. The audio amplifier of claim 12 wherein the driver output comprises at least a pair of transistors connected in a push-pull configuration.

14. The audio amplifier of claim 13 wherein the push-pull configuration comprises a PMOS transistor and an NMOS transistor.

15. The audio amplifier of claim 13 wherein the push-pull configuration is operable in a tri-state mode.

16. The audio amplifier of claim 12 wherein the driver stage comprises a plurality of electronic switches configured to enable the driver output.

17. The audio amplifier of claim 12 wherein the delay circuit comprises a digital controller configured to receive a clock frequency and to execute a machine readable program code.

18. The audio system of claim 12 wherein the predetermined time period is programmable.

19. The audio system of claim 12 wherein the predetermined time period is a function of the frequency compensation capacitor.

20. A method for suppressing transients at power up, comprising:
providing an output driver configured to drive a sound producing device;
providing a delay circuit configured to provide a turn-on signal to the output driver after a predetermined time period; and
turning on the output driver after the predetermined time period.

21. The method of claim 20 wherein the output driver comprises a push-pull configuration.

22. The method of claim 20 wherein the predetermined time period is a function of an operating point which is characterized by a gate-source (Vgs) voltage.

23. The method of claim 22 wherein the Vgs is about 1.0 Volt.

24. The method of claim 20 wherein the delay circuit comprises a trigger input configured to start a process for generating the turn-on signal.

25. The method of claim 20 wherein the delay circuit comprises a digital controller configured to receive a clock frequency and execute a machine readable program code stored in a memory.
